(19) United States
(12) Patent Application Publication
(10) Pub. No.: US 2022/0115238 A1
(43) Pub. Date: Apr. 14, 2022

(54) ETCHING METHOD, METHOD OF MANUFACTURING SEMICONDUCTOR CHIP, AND METHOD OF MANUFACTURING ARTICLE

(71) Applicant: KABUSHIKI KAISHA TOSHIBA, Tokyo (JP)

(72) Inventors: Takayuki TAJIMA, Sagamihara (JP); Kazuhito HIGUCHI, Yokohama (JP); Susumu OBATA, Yokohama (JP); Mitsuo SANO, Kamakura (JP)

(73) Assignee: KABUSHIKI KAISHA TOSHIBA, Tokyo (JP)

(21) Appl. No.: 17/357,350

(22) Filed: Jun. 24, 2021

(30) Foreign Application Priority Data
Oct. 9, 2020 (JP) 2020-171411

(51) Int. Cl. H01L 21/306; H01L 21/78; H01L 21/308

(52) U.S. Cl. CPC H01L 21/30604; H01L 21/308; H01L 21/78

(57) ABSTRACT

According to an embodiment, an etching method includes forming an uneven structure including a protruding portion on a surface of a semiconductor substrate, the protruding portion having a reverse tapered cross-sectional shape; forming a catalyst layer on the surface of the semiconductor substrate at a top surface of the protruding portion, the catalyst layer including a noble metal; and supplying an etching solution to the catalyst layer to etch the semiconductor substrate with an assist from the noble metal as a catalyst.

### CROSS-REFERENCE TO RELATED APPLICATIONS

This application is based upon and claims the benefit of priority from Japanese Patent Application No. 2020-171411, filed Oct. 9, 2020, the entire contents of which are incorporated herein by reference.

### FIELD

Embodiments described herein relate generally to an etching method, a method of manufacturing a semiconductor chip, and a method of manufacturing an article.

### BACKGROUND

Etching is known as a method of forming a hole or a groove in a semiconductor wafer.

As an etching method, for example, a method in which a mask layer is formed on a semiconductor wafer, the mask layer is patterned by laser scribing, and plasma-etching the semiconductor wafer using the patterned mask layer as an etching mask, is known.

As another etching method, metal assisted chemical etching (MacEtch) is known. The MacEtch is, for example, a method of etching a semiconductor substrate using a noble metal as a catalyst.

### BRIEF DESCRIPTION OF THE DRAWINGS

FIG. 1 is a cross-sectional view schematically showing a step of forming a first mask layer in an etching method according to an embodiment;

FIG. 2 is a cross-sectional view schematically showing a step of forming a semiconductor layer in the etching method according to the embodiment;

FIG. 3 is a cross-sectional view schematically showing a step of removing the first mask layer in the etching method according to the embodiment;

FIG. 4 is a cross-sectional view schematically showing a step of forming a second mask layer in the etching method according to the embodiment;

FIG. 5 is a cross-sectional view schematically showing a step of forming a catalyst layer in the etching method according to the embodiment;

FIG. 6 is a cross-sectional view schematically showing a state at the start of an etching step in the etching method according to the embodiment;

FIG. 7 is a cross-sectional view schematically showing a state after a certain period of time from the state shown in FIG. 6;

FIG. 8 is a cross-sectional view schematically showing a semiconductor substrate to be etched in a Comparative Example;

FIG. 9 is a cross-sectional view schematically showing a step of forming a catalyst layer in the Comparative Example;

FIG. 10 is a cross-sectional view schematically showing an etching step in the Comparative Example;

FIG. 11 is a cross-sectional view schematically showing a semiconductor substrate to be etched in the etching method according to the embodiment;

FIG. 12 is a cross-sectional view schematically showing a step of forming a catalyst layer in the etching method according to the embodiment;

FIG. 13 is a cross-sectional view schematically showing an etching step in the etching method according to the embodiment;

FIG. 14 is a cross-sectional view schematically showing a semiconductor substrate including an inorganic material layer in an example of the step of forming the first mask layer.

FIG. 15 is a cross-sectional view schematically showing a structure obtained by forming a resist layer on the semiconductor substrate shown in FIG. 14;

FIG. 16 is a cross-sectional view schematically showing a structure obtained by etching the inorganic material layer shown in FIG. 15;

FIG. 17 is a cross-sectional view schematically showing a structure obtained by removing the resist layer from the semiconductor substrate shown in FIG. 16;

FIG. 18 is a cross-sectional view schematically showing a semiconductor substrate including a resist layer and an inorganic material layer in the step of forming the first mask layer having stepped sidewalls.

FIG. 19 is a cross-sectional view schematically showing a structure obtained by removing the resist layer from the semiconductor substrate shown in FIG. 18;

FIG. 20 is a cross-sectional view schematically showing a structure obtained by forming a resist layer on the semiconductor substrate shown in FIG. 19;

FIG. 21 is a cross-sectional view schematically showing a structure obtained by etching the inorganic material layer shown in FIG. 20;

FIG. 22 is a cross-sectional view schematically showing a structure obtained by removing the resist layer from the semiconductor substrate shown in FIG. 21;

FIG. 23 is a cross-sectional view schematically showing a structure obtained by forming a resist layer on the semiconductor substrate shown in FIG. 22;

FIG. 24 is a cross-sectional view schematically showing a structure obtained by etching the inorganic material layer shown in FIG. 23;

FIG. 25 is a cross-sectional view schematically showing a structure obtained by removing the resist layer from the semiconductor substrate shown in FIG. 24;

FIG. 26 is a plan view schematically showing a top surface of the semiconductor substrate shown in FIG. 3.

FIG. 27 is a cross-sectional view of the semiconductor substrate, taken along the line XXVII-XXVII shown in FIG. 26;

FIG. 28 is a micrograph showing a cross-section of a silicon substrate on which a protruding portion, the second mask layer, and the catalyst layer are formed; and

FIG. 29 is a micrograph showing a cross-section of a structure obtained by etching the structure shown in FIG. 28.

### DETAILED DESCRIPTION

An etching method according to the first embodiment comprises forming an uneven structure including a protruding portion on a surface of a semiconductor substrate, the protruding portion having a reverse tapered cross-sectional shape; forming a catalyst layer on the surface of the semiconductor substrate at a top surface of the protruding portion, the catalyst layer including a noble metal; and supplying an etching solution to the catalyst layer to etch the semiconductor substrate with an assist from the noble metal as a catalyst.

A method of manufacturing a semiconductor chip according to the second embodiment comprises etching a semiconductor wafer by the etching method according to the first embodiment to singulate the semiconductor wafer into semiconductor chips, the surface of the semiconductor substrate being a surface of the semiconductor wafer.

A method of manufacturing an article according to the third embodiment comprises etching the surface of the semiconductor substrate by the etching method according to the first embodiment.

Embodiments will be described in detail below with reference to the accompanying drawings. The same reference numerals denote constituent elements which achieve the same or similar functions throughout all the drawings, and repeat explanations will be omitted.

The terms used herein and in the accompanying claims are defined as follows. The term “micrograph” refers to a scanning electron micrograph. The term “opening” refers to a space extending from one of the surfaces of a layer to the other of the surfaces of the layer, such as a through-hole or a groove. With regard to a portion without an entity such as an opening, the term “forward tapered” refers to a shape tapered from the opening toward the deeper side, that is, a shape tapered from the surface side toward the base side. With regard to a portion with an entity such as a mask layer, the term “forward tapered” refers to a shape tapered from the undersurface toward the top surface, that is, a shape tapered from the base side toward the surface side.

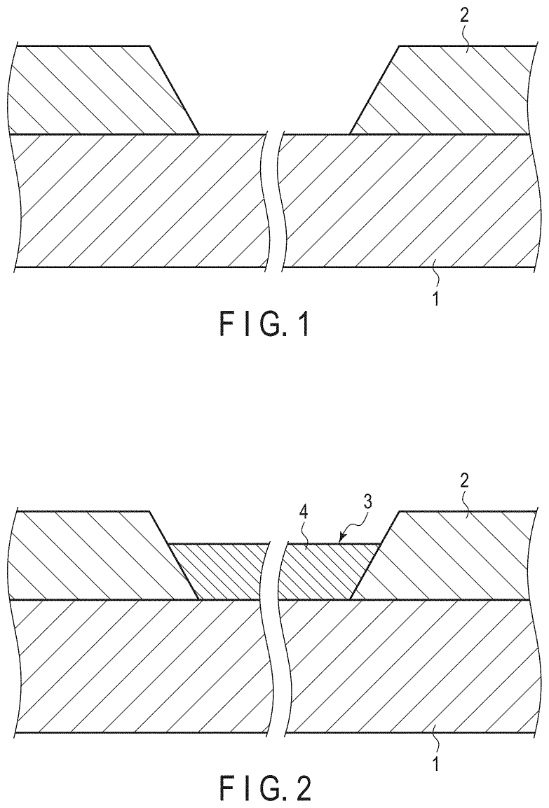

First, an etching method according to an embodiment will be described with reference to FIGS. 1 to 7.

In the etching method, first, a semiconductor substrate 1 is prepared as shown in FIG. 1.

At least a part of the surface of the semiconductor substrate 1 is made of a semiconductor. The semiconductor is selected from, for example, silicon (Si), germanium (Ge), semiconductors consisting of compounds of group III and group V elements such as gallium arsenide (GaAs) and gallium nitride (GaN), and silicon carbide (SiC). As one example, the semiconductor substrate 1 contains silicon. The term “group” used herein is “a group” in the short-form periodic table.

The semiconductor substrate 1 is, for example, a semiconductor wafer. The semiconductor wafer may be doped with impurities, or semiconductor elements such as transistors or diodes may be formed on the semiconductor wafer. Also, the main surface of the semiconductor wafer may be parallel to any crystal plane of the semiconductor.

Then, a first mask layer 2 is formed on the surface of the semiconductor substrate 1, as shown in FIG. 1.

The first mask layer 2 is a layer for forming a semiconductor layer 3 (described later) into a pattern shape on the surface of the semiconductor substrate 1. The first mask layer 2 has one or more openings having a forward tapered cross-sectional shape.

Any material can be used as the material of the first mask layer 2, provided that the material is sufficiently resistant to the deposition process of the semiconductor layer 3 described later. The material of the first mask layer 2 is preferably one that can be removed at a higher etching rate than those of the semiconductor substrate 1 and the semiconductor layer 3. Examples of the material of the first mask layer 2 include inorganic materials such as silicon oxide.

The first mask layer 2 can be formed by, for example, an existing semiconductor process. The first mask layer 2 can be formed by, for example, formation of a layer made of the foregoing inorganic material, formation of a resist pattern by photolithography, and patterning of the layer made of the inorganic material by reactive ion etching using a resist pattern as an etching mask. A specific example of the method of forming the first mask layer 2 will be described later.

The thickness of the first mask layer 2 is preferably in a range of 0.2 pm to 1 pm, and more preferably in a range of 0.35 pm to 0.5 pm. If the first mask layer 2 is too thin, it is difficult to increase the height of a protruding portion 4 described later. Though the upper limit of the thickness of the first mask layer 2 is not particularly limited, it is, for example, 3 μm or less.

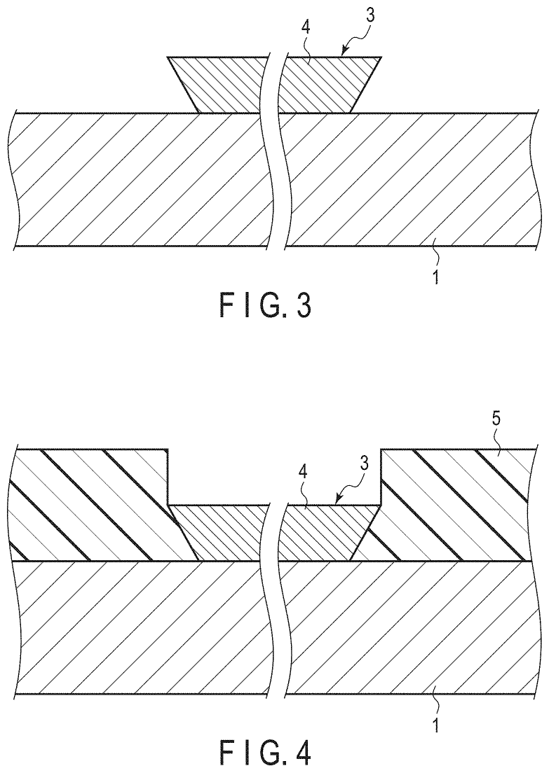

Then, a semiconductor layer 3 which fills at least a lower portion of the openings of the first mask layer 2 is formed on the surface of the semiconductor substrate 1 at positions corresponding to these openings, as shown in FIG. 2. The semiconductor layer 3 is formed to cover the entire region of the surface of the semiconductor substrate 1 that is not covered with the first mask layer 2. In this manner, each portion of the semiconductor layer 3 located in the opening of the first mask layer 2 is obtained as the protruding portion 4.

The semiconductor layer 3 is made of, for example, a semiconductor. The semiconductor may be the semiconductor illustrated as a material of the semiconductor substrate 1. The material of the semiconductor layer 3 may be the same as the material of the semiconductor substrate 1. The material of the semiconductor layer 3 may be different from the material of the semiconductor substrate 1, provided that the material can be etched under the etching conditions for etching the semiconductor substrate 1.

The semiconductor layer 3 can be formed by, for example, epitaxial growth. As one example, the semiconductor layer 3 can be formed by epitaxial growth of silicon.

Then, the first mask layer 2 is removed, as shown in FIG. 3. The first mask layer 2 can be removed by, for example, etching.

Then, a second mask layer 5 is formed on the surface of the semiconductor substrate 1, as shown in FIG. 4. The first mask layer 2 may not be removed and can be used as the second mask layer 5.

The second mask layer 5 has an opening at a position corresponding to the protruding portion 4. The second mask layer 5 is formed so as to cover the entire region of the surface of the semiconductor substrate 1 that is not covered with the semiconductor layer 3, and so that the entire sidewall of the protruding portion 4 comes into contact with the sidewall of each opening. The second mask layer 5 has a top surface that is flush with or higher than the top surface of the protruding portion 4.

The second mask layer 5 is etching-resistant to an etching solution for etching the semiconductor substrate 1.

Any material can be used as the material of the second mask layer 5. The material of the second mask layer 5 is preferably an organic material such as polyimide, a fluorine resin, a phenolic resin, an acrylic resin or a novolak resin.

The second mask layer 5 is preferably formed using a liquid resist. The liquid resist includes, for example, the foregoing organic material. With the use of a liquid resist, it will be easy to make a gap less likely to be generated between the sidewalls of the protruding portion 4 and the sidewalls of the opening of the second mask layer 5. When such a gap is generated, the effect of suppressing the etching from progressing in an undesired direction becomes small in the etching utilizing the catalyst layer described later.

A positive photoresist is preferably used as the liquid resist. Since the sidewalls of the protruding portion 4 are inclined so that the protruding portion 4 has a reverse tapered cross-sectional shape, it is difficult to expose a portion of a resist layer located under the sidewalls of the protruding portion 4 to light. When a positive photoresist is used, a portion of a resist layer located under the sidewalls of the protruding portion 4 need not be exposed to light; therefore, the second mask layer 5 can be formed at a high shape precision.

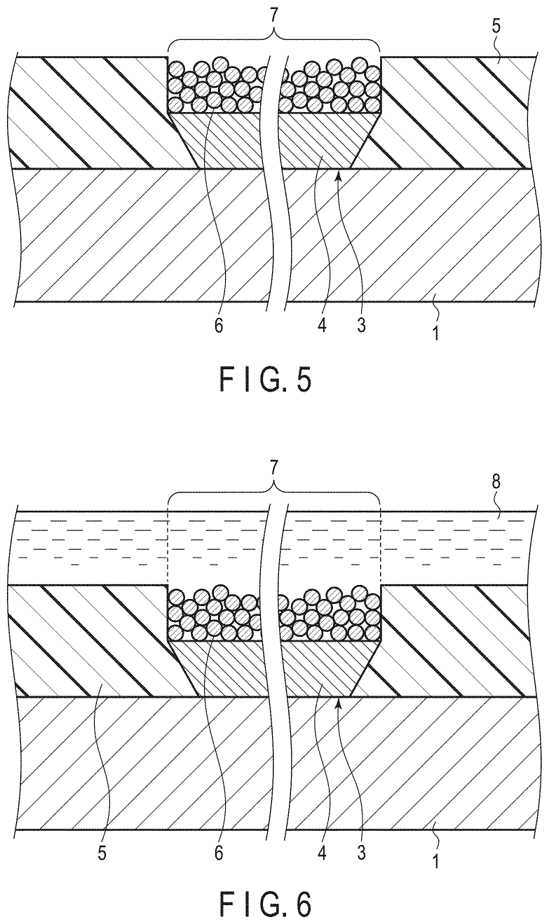

Then, a catalyst layer 7 including a noble metal is formed on the top surface of the protruding portion 4, as shown in FIG. 5. The catalyst layer 7 includes, for example, noble metal particles 6. The noble metal is, for example, at least one metal selected from the group consisting of Au, Ag, Pt, Pd, Ru and Rh.

The thickness of the catalyst layer 7 is preferably in a range of 0.01 μm to 0.3 μm, and more preferably in a range of 0.05 μm to 0.2 μm. When the catalyst layer 7 is too thick, an etching solution 8 (described later) cannot easily reach the semiconductor substrate 1, thus making it difficult to cause etching to progress. When the catalyst layer 7 is too thin, the ratio of the total surface area of the noble metal particles 6 to the area to be etched is too small, thus making it difficult to cause etching to progress.

The thickness of the catalyst layer 7 is the distance from the top surface of the catalyst layer 7 to the top surface of the protruding portion 4 in the image, observed by the scanning electron microscope, of the cross-section of the catalyst layer 7 that is parallel to the thickness direction of the catalyst layer 7.

The catalyst layer 7 covers at least a part of the top surface of the protruding portion 4. The catalyst layer 7 may have a discontinuous portion.

The noble metal particles 6 are preferably spherical. The noble metal particles 6 may be in any other shape such as a rod shape or a plate shape. The noble metal particles 6 serve as a catalyst for the oxidation reaction of the surface of a semiconductor that is in contact with the noble metal particles 6.

The particle size of each of the noble metal particles 6 is preferably in a range of 0.001 μm to 1 μm, and more preferably in a range of 0.01 μm to 0.5 μm. The “particle size” is a value obtained by the following method. First, an image of the main surface of the catalyst layer 7 is captured by the scanning electron microscope at a magnification in a range of 10000 to 100000. Next, the area of each of the noble metal particles 6 is obtained from the image. Then, assuming that each of the noble metal particles 6 is spherical, the diameter of each of the noble metal particles 6 is obtained from the foregoing area. This diameter is defined as the “particle size” of the noble metal particles 6.

The catalyst layer 7 can be formed by, for example, electroplating, reduction plating, or displacement plating. The catalyst layer 7 may be formed by applying a dispersion containing the noble metal particles 6, or vapor phase deposition such as evaporation and sputtering. Of these methods, the displacement plating is particularly preferable because the noble metal can be deposited directly and uniformly on the protruding portion 4. As an example, formation of the catalyst layer 7 by the displacement plating will be described below.

For the deposition of a noble metal by the displacement plating, it is possible to use an aqueous solution of tetrachloroaurate (III) acid or a silver nitrate solution, for example. Below is a description of an example of this process.

The displacement plating solution is, for example, a mixture of an aqueous solution of hydrogen tetrachloroaurate (III) tetrahydrate and hydrofluoric acid. The hydrofluoric acid has a function of removing a native oxide film from the surface of the semiconductor substrate 1.

When the semiconductor substrate 1 is immersed in the displacement plating solution, a native oxide film is removed from the surface of the semiconductor substrate 1, and a noble metal, gold in this example, is deposited on the top surface of the protruding portion 4. Consequently, the catalyst layer 7 is obtained.

The concentration of hydrogen tetrachloroaurate (III) tetrahydrate in the displacement plating solution is preferably in a range of 0.0001 mol/L to 0.01 mol/L. Also, the concentration of hydrogen fluoride in the displacement plating solution is preferably in a range of 0.1 mol/L to 6.5 mol/L.

The displacement plating solution may further include a sulfur-containing complexing agent. Alternatively, the displacement plating solution may further include glycine and citric acid.

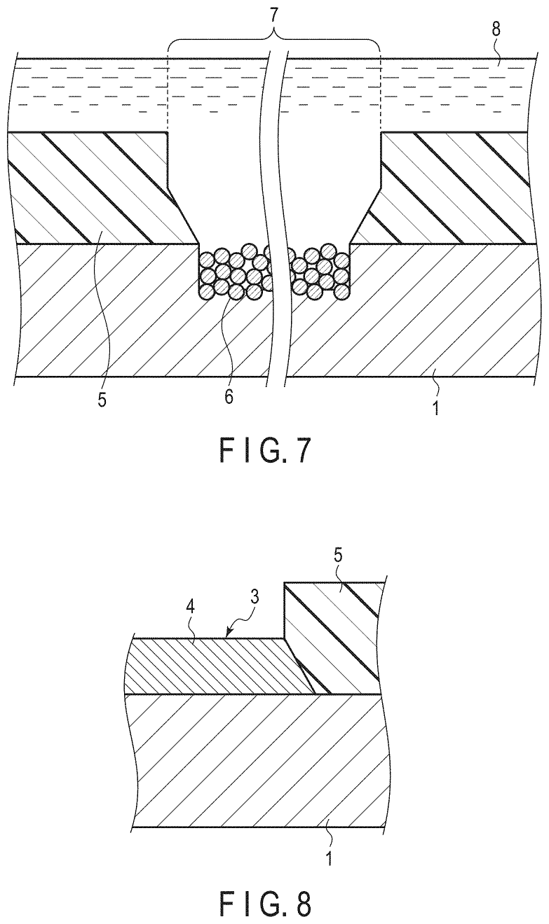

Then, an etching solution 8 is supplied to the catalyst layer 7 as shown in FIG. 6. For example, the semiconductor substrate 1 on which the protruding portion 4, second mask layer 5, and catalyst layer 7 are formed is immersed in the etching solution 8. The etching solution 8 includes, for example, a corrosive agent and an oxidizer. The etching solution 8 may further include ammonium fluoride.

When the etching solution 8 is brought into contact with the surface of the semiconductor substrate 1, a portion of the surface to which the noble metal particles 6 are close is oxidized by the oxidizer and the oxide is dissolved away by the corrosive agent. Therefore, the etching solution 8 etches the surface of the semiconductor substrate 1 in the vertical direction (i.e., the thickness direction described above) with an assist from the catalyst layer 7 as a catalyst, as shown in FIG. 7. The corrosive agent dissolves the oxide. The oxide is, for example, SiO₂. The corrosive agent is, for example, hydrofluoric acid.

The concentration of hydrogen fluoride in the etching solution 8 is preferably in a range of 0.4 mol/L to 20 mol/L, more preferably in a range of 0.8 mol/L to 16 mol/L, and still more preferably in a range of 2 mol/L to 10 mol/L. When the concentration of hydrogen fluoride is too low, a high etching rate is difficult to achieve. When the concentration of hydrogen fluoride is too high, controllability of etching in the processing direction (e.g., the thickness direction of the semiconductor substrate 1) may be lowered.

The oxidizer in the etching solution 8 can be selected from, for example, hydrogen peroxide, nitric acid, AgNO₃, KAuC1₄, HAuCl₄, K₂PtCl₆, H₂PtCl₆, Fe(NO₃)₃, Ni (NO₃)₂, Mg (NO₃)₂, Na₂S₂O₈, K₂S₂O₈, KMnO₄ and K₂Cr₂O₇. Hydrogen peroxide is preferred as the oxidizer because it neither generates any harmful byproduct nor contaminates a semiconductor element.

The concentration of the oxidizer such as hydrogen peroxide in the etching solution 8 is preferably in a range of 0.2 mol/L to 8 mol/L, more preferably in a range of 0.5 mol/L to 5 mol/L, and still more preferably in a range of 0.5 mol/L to 4 mol/L. When the concentration of the oxidizer is too low, a high etching rate is difficult to achieve. When the concentration of the oxidizer is excessively high, excess side etching may occur.

The foregoing etching method may generate a needle-like residual portion in the semiconductor substrate 1.

The needle-like residual portion may be removed by, for example, at least one of wet etching or dry etching. The etching solution in the wet etching can be selected from a mixture of hydrofluoric acid, nitric acid and acetic acid, tetramethylammonium hydroxide (TMAH), KOH, and the like. Examples of the dry etching include plasma etching using gas such as SF₆, CF₄, C₂F₆, CSFB, CClF₂, CCl₄, PCl₃, or CBrF₃.

The etching solution 8 may be supplied to the catalyst layer 7 after the second mask layer 5 is removed.

In the method shown in FIGS. 1 to 7, the semiconductor substrate 1 is etched as described above.

Incidentally, when the semiconductor substrate 1 is etched without being provided with an uneven structure including the protruding portion 4, a portion remaining after the etching tends to be porous. This will be explained below.

In an etching method that is the same as the etching method described with reference to FIGS. 1 to 7 except that an uneven structure including the protruding portion 4 is not provided, etching that is promoted by the noble metal particles 6 located relatively far from the contour of the opening of the second mask layer 5 progresses in the thickness direction of the semiconductor substrate 1. Thus, as the etching progresses, the noble metal particles 6 move in the thickness direction of the semiconductor substrate 1.

However, etching that is promoted by some of the noble metal particles 6 located near the contour of the opening of the second mask layer 5 does not progress in the thickness direction of the semiconductor substrate 1. As a result, some of the noble metal particles 6 move to a portion of the surface region of the semiconductor substrate 1 that is located right under the second mask layer 5. The direction in which the etching promoted by the noble metal particles 6 that have moved to the portion located right under the second mask layer 5 progresses is affected by the progression direction of the past etching and the crystal structure of the semiconductor substrate 1. Therefore, etching progresses in various directions in the portion located right under the second mask layer 5. Consequently, the residual portion after the etching, that is, the portion located right under the second mask layer 5, tends to be porous.

According to an etching method that is the same as the etching method described with reference to FIGS. 1 to 7 except that the cross-sectional shape of the protruding portion 4 is a rectangular shape, the residual portion after the etching is less likely to be porous, as explained below. Namely, in such an etching method, the etching promoted by the noble metal particles 6 occurs only within the range surrounded by the sidewalls of the protruding portion 4 in the initial stage of the etching. Therefore, not only the etching that is promoted by the noble metal particles 6 located relatively far from the contour of the opening of the second mask layer 5, but also the etching that is promoted by the noble metal particles 6 located near the contour of the opening of the second mask layer 5 progresses in the thickness direction of the semiconductor substrate 1.

If the direction in which etching progresses is restricted to a single direction in the initial stage of the etching, subsequent etching may also progress in said direction. Namely, if the protruding portion 4 having a rectangular cross-sectional shape is provided, etching is directed to progress in the thickness direction of the semiconductor substrate 1 in the initial stage of the etching, and the noble metal particles 6 are less likely to move to the portion located right under the second mask layer 5 in the subsequent stage as well. Thus, the residual portion after the etching, that is, the portion located right under the second mask layer 5, is less likely to be porous.

However, when the design in which the protruding portion 4 has a rectangular cross-sectional shape is adopted, the protruding portion 4 which has a forward tapered cross-sectional shape (hereinafter, this protruding portion 4 will be referred to as a “forward tapered protruding portion”) may be obtained, as shown in FIG. 8, due to a variation in the manufacture.

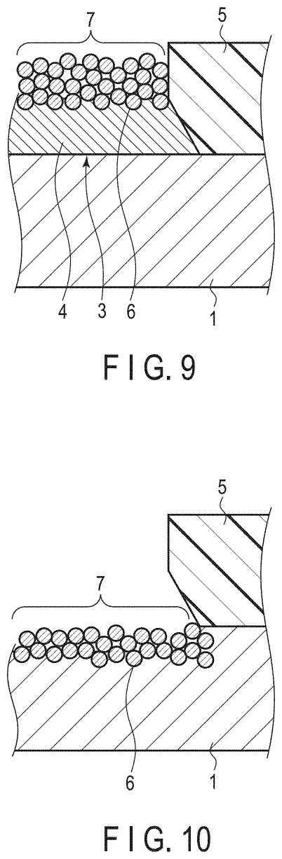

When the catalyst layer 7 is formed on the protruding portion 4 having such a cross-sectional shape by the method described with reference to FIG. 5, and etched by the method described with reference to FIGS. 6 and 7, as shown in FIG. 9, the etching progresses as shown in FIG. 10. Namely, since the protruding portion 4 has a forward tapered cross-sectional shape, etching that is promoted by some of the noble metal particles 6 located near the contour of the opening of the second mask layer 5 may progress in a direction inclined with respect to the thickness direction of the semiconductor substrate 1, such as a direction along the sidewalls of the forward tapered protruding portion, in the initial stage of the etching. Therefore, in the initial stage of the etching, some of the noble metal particles 6 located near the contour of the opening of the second mask layer 5 move to a direction inclined with respect to the thickness direction of the semiconductor substrate 1, such as a direction along the sidewalls of the forward tapered protruding portion. Some of the noble metal particles 6 move to the portion of the surface region of the semiconductor substrate 1 that is located right under the second mask layer 5, as the etching further progresses. Consequently, the residual portion after the etching, that is, the portion of the surface region of the semiconductor substrate 1 that is located right under the second mask layer 5, tends to be porous, although the degree to which said portion tends to be porous is not as high as that of the case where the protruding portion 4 is omitted.

On the other hand, according to the etching method described with reference to FIGS. 1 to 7, the residual portion after the etching is less likely to be porous. This will be described below.

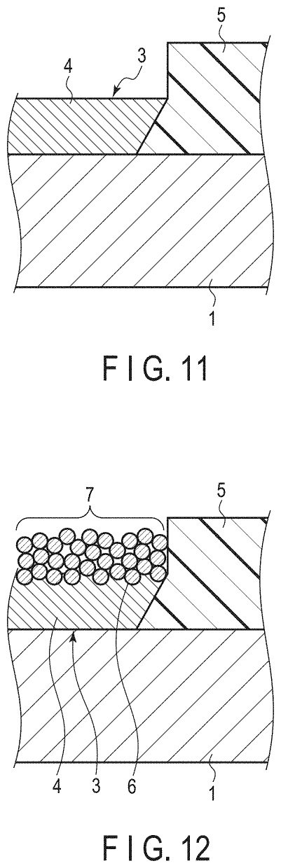

First, a structure shown in FIG. 11 is obtained by the method described with reference to FIGS. 1 to 4. A structure shown in FIG. 12 is then obtained when the catalyst layer 7 is formed on the structure shown in FIG. 11 by the method described with reference to FIG. 5.

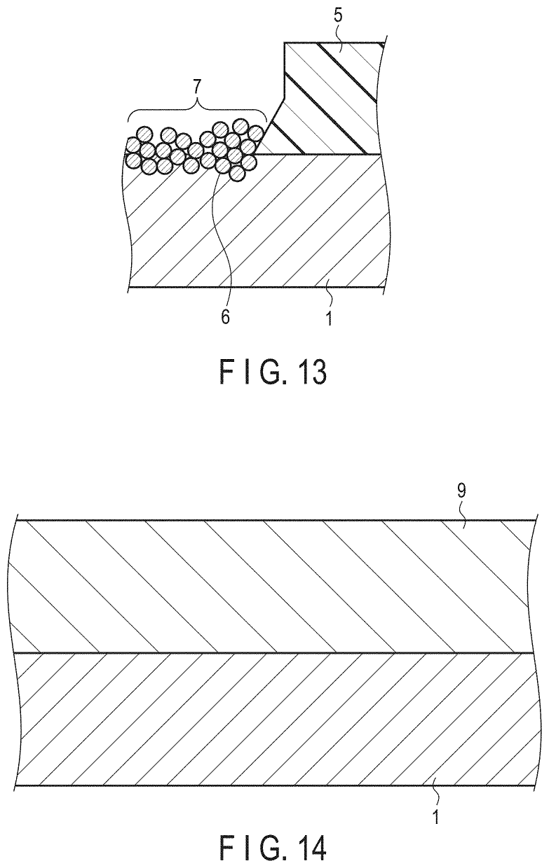

A structure shown in FIG. 13 is then obtained when the structure shown in FIG. 12 is etched by the method described with reference to FIGS. 6 and 7. The etching promoted by the noble metal particles 6 occurs only within the range surrounded by the sidewalls of the protruding portion 4 in the initial stage of the etching. Also, since the protruding portion 4 has a reverse tapered cross-sectional shape, the noble metal particles 6 located near the contour of the opening of the second mask layer 5 are less likely to move to the portion of the surface region of the semiconductor substrate 1 that is located right under the second mask layer 5 in the subsequent stage as well. When the design in which the protruding portion 4 has a reverse tapered cross-sectional shape is adopted, the possibility that the protruding portion 4 having a forward tapered cross-sectional shape will be formed is low even when there is a variation in the manufacture. Therefore, according to the etching method described with reference to FIGS. 1 to 7, the residual portion after the etching is less likely to be porous.

In the foregoing etching method, the first mask layer 2 can be formed by, for example, the method described below.

First, an inorganic material layer 9 is formed on the surface of the semiconductor substrate 1, as shown in FIG. 14. Examples of the material of the inorganic material layer 9 include inorganic materials such as silicon oxide. The inorganic material layer 9 can be formed by, for example, deposition by vapor phase deposition, or oxidizing or nitriding of the surface region of the semiconductor substrate 1.

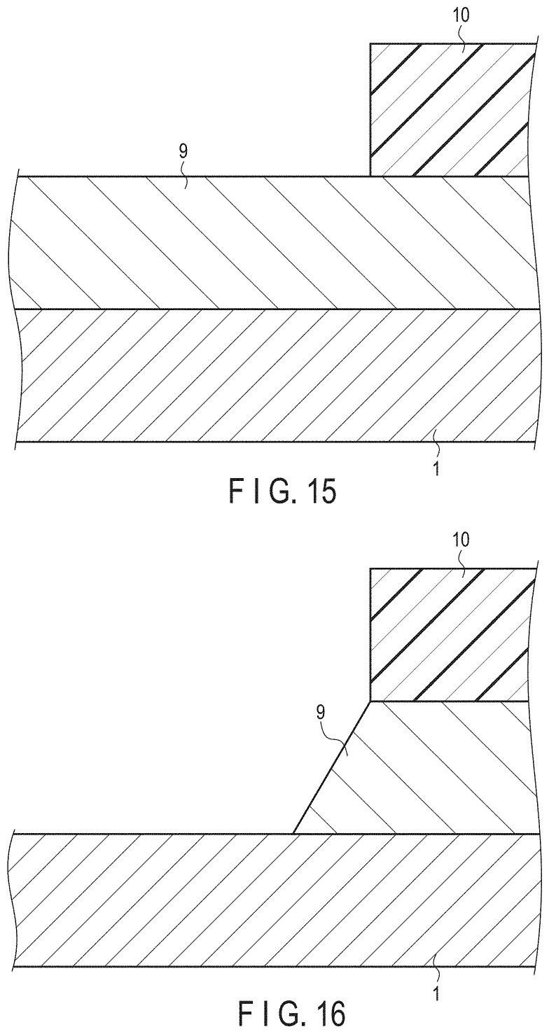

Then, as shown in FIG. 15, a resist layer 10 is formed on a part of the surface of the inorganic material layer 9 shown in FIG. 14. Examples of the material of the resist layer 10 include organic materials such as polyimide, a fluorine resin, a phenolic resin, an acrylic resin and a novolak resin. The resist layer 10 can be formed by, for example, photolithography.

Then, the inorganic material layer 9 shown in FIG. 15 is etched using the resist layer 10 as an etching mask, as shown in FIG. 16. The etching is, for example, reactive ion etching. In the reactive ion etching, an etching gas containing fluorocarbon-based gas is used to deposit a fluorocarbon polymer generated from this gas on the sidewalls of the opening formed by the etching, so that the thickness of the deposited fluorocarbon polymer is larger on the lower side of the sidewalls. High-frequency output or a bias voltage applied to an etching target at the time of etching is adjusted to control a ratio between an etching amount by isotropic etching originating in the etching gas and an etching amount by anisotropic etching attributed to an energy of ions generated from the etching gas. Through the above control, the opening having a forward tapered cross-sectional shape shown in FIG. 16 can be formed. When controlling the ratio of the etching amount based on the etching condition in this manner, reducing the etching amount in the depth direction by decreasing the high-frequency output allows for reduction of the taper angle. A method of forming such an opening is also described in the following patent literatures:

Jpn. Pat. Appin. KOKAI Publication No. H10-7082

International Publication No. 2010/150720

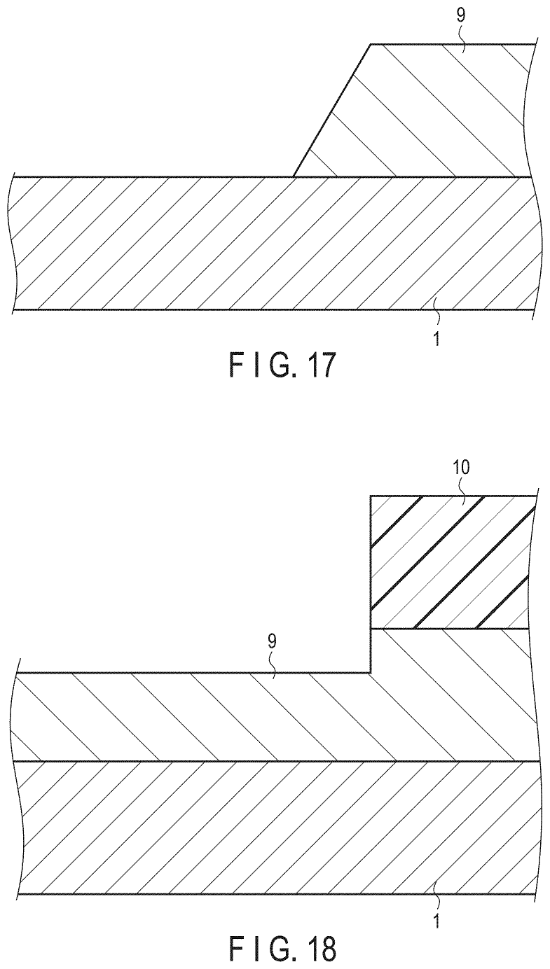

Then, as shown in FIG. 17, the resist layer 10 is removed from the structure shown in FIG. 16. The resist layer 10 can be removed by, for example, etching.

The inorganic material layer 9 patterned in this manner is obtained as the first mask layer 2.

In the method of forming the first mask layer 2 described with reference to FIGS. 14 to 17, the sidewalls of the first mask layer 2 are an inclined surface; however, the sidewalls of the first mask layer 2 may be stepped sidewalls. When the sidewalls of the first mask layer 2 are stepped sidewalls, the protruding portion 4 which has stepped sidewalls can be formed. A specific example of the method of forming the first mask layer 2 having stepped sidewalls will be described below.

First, a structure shown in FIG. 15 is prepared. Then, a part of the inorganic material layer 9 shown in

FIG. 15 is etched using the resist layer 10 as an etching mask, as shown in FIG. 18. Specifically, the etching is performed so that the amount of reduction of the thickness of the inorganic material layer 9 by the etching will be smaller than the thickness of the inorganic material layer 9 before the etching. Namely, the inorganic material layer 9 is etched so that the portion of the inorganic material layer 9 not covered with the resist layer 10 will not be removed completely. The etching is, for example, reactive ion etching. In the description below, the etching of the inorganic material layer 9 is performed by reactive ion etching.

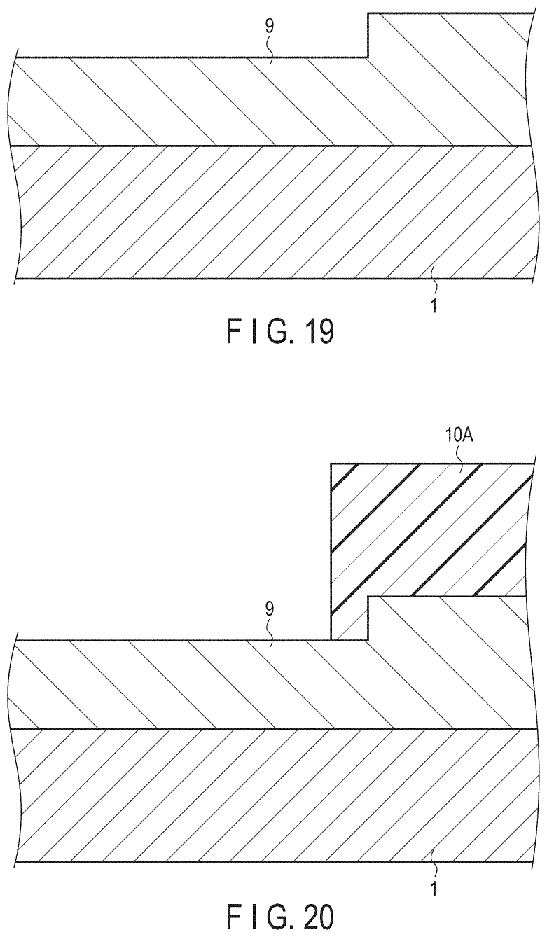

Then, as shown in FIG. 19, the resist layer 10 is removed from the structure shown in FIG. 18.

Then, as shown in FIG. 20, a resist layer 10A is formed on a part of the surface of the inorganic material layer 9 shown in FIG. 19. The resist layer 10A is formed to cover the portion of the inorganic material layer 9 covered with the resist layer 10 as shown in FIG. 15, and the peripheral edge of the portion of the inorganic material layer 9 whose thickness has been reduced by the etching described with reference to FIG. 18. Namely, the resist layer 10A is formed to have an opening in the center of the portion of the inorganic material layer 9 whose thickness has been reduced by the etching described with reference to FIG. 18. The material used for the resist layer 10A and a resist layer 10B described later and the method of forming these resist layers are the same as those described for the resist layer 10.

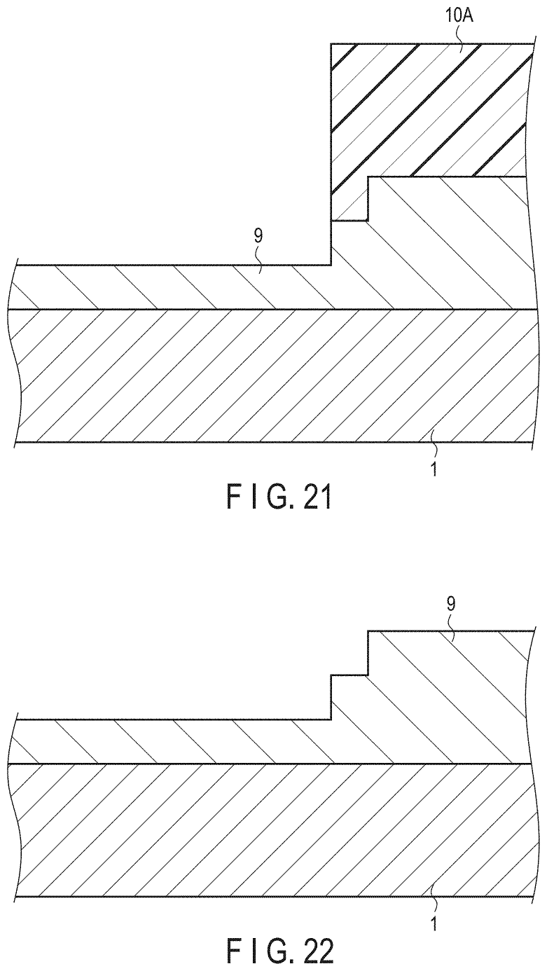

Then, a part of the inorganic material layer 9 shown in FIG. 20 is etched using the resist layer 10A as an etching mask, as shown in FIG. 21. Specifically, the etching is performed so that the amount of reduction of the thickness of the inorganic material layer 9 by the etching will be smaller than the thickness of the inorganic material layer 9 before the etching. Namely, the inorganic material layer 9 is etched so that the portion of the inorganic material layer 9 not covered with the resist layer 10A will not be removed completely.

Then, as shown in FIG. 22, the resist layer 10A is removed from the structure shown in FIG. 21.

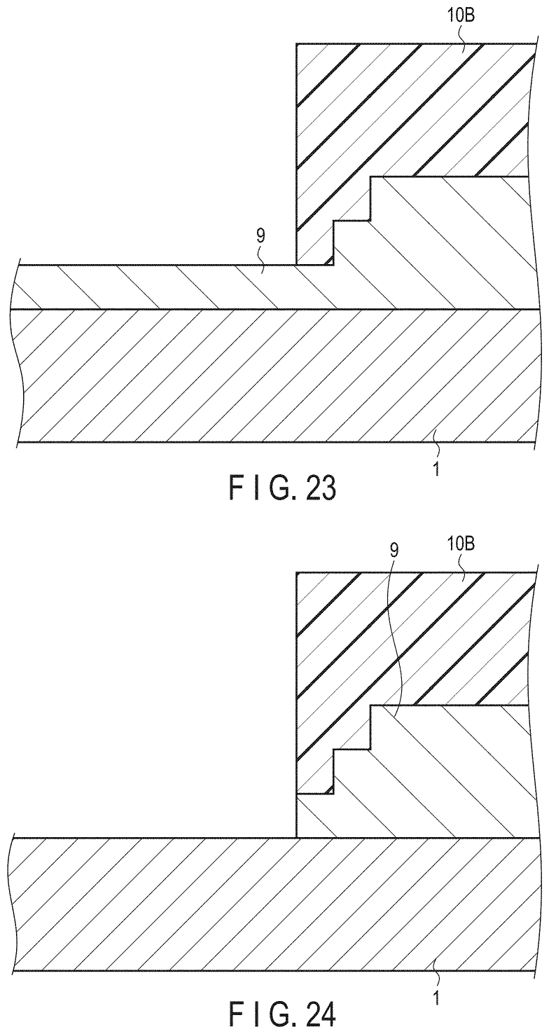

Then, as shown in FIG. 23, a resist layer 10B is formed on a part of the surface of the inorganic material layer 9 shown in FIG. 22. The resist layer 10B is formed to cover the portion of the inorganic material layer 9 covered with the resist layer 10A as shown in FIG. 20, and the peripheral edge of the portion of the inorganic material layer 9 whose thickness has been reduced by the etching described with reference to FIG. 21. Namely, the resist layer 10B is formed to have an opening in the center of the portion of the inorganic material layer 9 whose thickness has been reduced by the etching described with reference to FIG. 21.

Then, the inorganic material layer 9 shown in FIG. 23 is etched using the resist layer 10B as an etching mask, as shown in FIG. 24. Specifically, the inorganic material layer 9 is etched so that the portion of the inorganic material layer 9 not covered with the resist layer 10B will be removed completely.

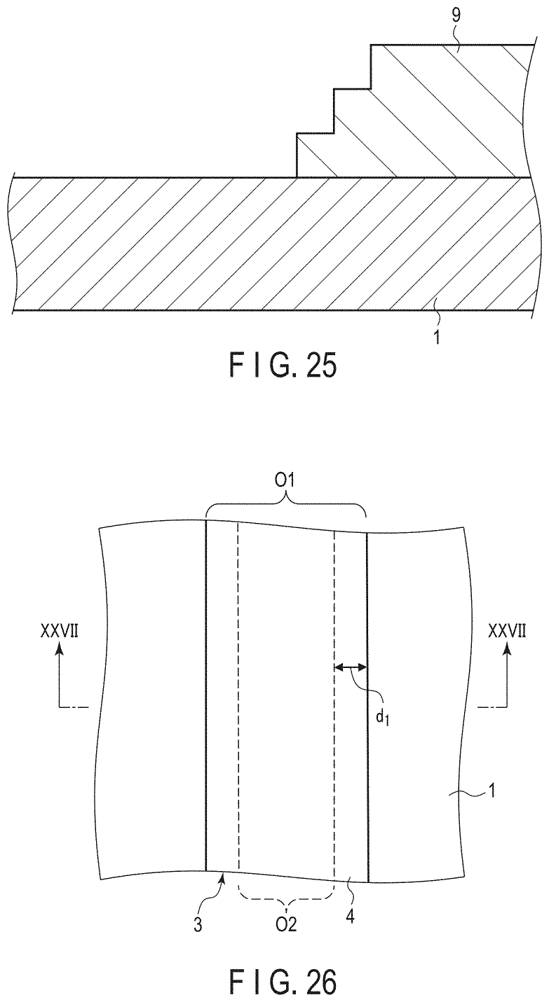

Then, as shown in FIG. 25, the resist layer 10 is removed from the structure shown in FIG. 24.

The inorganic material layer 9 patterned in this manner is obtained as the first mask layer 2 having stepped sidewalls.

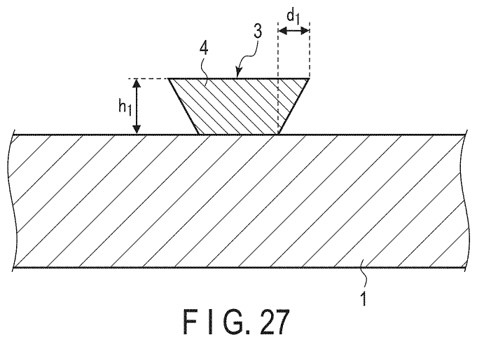

In the foregoing etching method, the dimensions of the protruding portion 4 and the dimensions of the second mask layer 5 are preferably set as described below. The dimensions of the protruding portion 4 will be described below with reference to FIGS. 26 and 27.

FIG. 26 is a plan view schematically showing the top surface of the semiconductor substrate shown in FIG. 3. In FIG. 26, the reference symbol 01 represents a first orthogonal projection of the top surface of the protruding portion 4 to a plane parallel to the surface of the semiconductor substrate 1. Also, in FIG. 26, the reference symbol 02 represents a second orthogonal projection of the lowest portion of the protruding portion 4 to a plane parallel to the surface of the semiconductor substrate 1. The lowest portion of the protruding portion 4 refers to the portion of the protruding portion 4 that is in contact with the semiconductor substrate 1. The distance d₁ shown in FIG. 26 is the distance from the contour of the first orthogonal projection O1 to the contour of the second orthogonal projection O2.

FIG. 27 is a cross-sectional view of the semiconductor substrate, taken along the line XXVII-XXVII shown in FIG. 26. The height hi shown in FIG. 27 is the height of the protruding portion 4. As shown in FIG. 27, the height h₁ of the protruding portion 4 is the distance from the top surface of the protruding portion 4 to the lowest portion of the protruding portion 4.

The height h₁ of the protruding portion 4 is preferably in a range of 0.15 μm to 0.5 μm, and more preferably in a range of 0.25 μm to 0.4 μm. If the height h₁ is too small, the noble metal particles 6 tend to move to the portion of the surface region of the semiconductor substrate 1 that is located right under the second mask layer 5 in the etching step utilizing the catalyst layer 7. Though the upper limit of the height hi is not particularly limited, it is usually 10 μm or less.

Herein, the “height h₁” is a value obtained by the following method. First, an image of the cross-section of the semiconductor substrate 1 including the protruding portion 4 is captured by the scanning electron microscope at a magnification in a range of 10000 to 100000. Then, the height of the protruding portion 4 in the image is measured. Specifically, the height of the left sidewall of the protruding portion 4 and the height of the right sidewall of the protruding portion 4 are measured. When the heights of the left and right sidewalls of the protruding portion 4 are the same, the height of one of the sidewalls is defined as “height h₁.” When the heights of the left and right sidewalls of the protruding portion 4 are different, the height of a lower sidewall is defined as “height h.”

The distance di is preferably in a range of 0.04 μm to 0.5 μm, and more preferably in a range of 0.05 μm to 0.3 μm. Since the protruding portion 4 has a reverse tapered cross-sectional shape, the amount of the noble metal particles 6 increases in the portion of the catalyst layer 7 that is located near the sidewalls of the protruding portion 4, as the etching progresses. If the distance di is too large, said increase amount will be excessive, likely resulting in a decrease in the etching uniformity. If the distance di is reduced, the cross-sectional shape of the protruding portion 4 may become a forward tapered shape due to a variation in the manufacture.

The distance di can be obtained from the image of the cross-section of the semiconductor substrate 1 including the protruding portion 4 captured by the scanning electron microscope at a magnification in a range of 10000 to 100000.

The ratio h₁/d₁ of the height h₁ to the distance d₁ is preferably in a range of 1 to 12, and more preferably in a range of 2 to 7. If the ratio h₁/d₁ is too small, the increase in the amount of the noble metal particles 6 near the sidewalls of the protruding portion 4 due to the progress of the etching will be excessive, likely resulting in a decrease in the etching uniformity. If the ratio h₁/d₁ is increased, the cross-sectional shape of the protruding portion 4 will highly likely be forward tapered due to a variation in the manufacture.

In addition, the thickness t₁ of the second mask layer 5 is preferably in a range of 0.15 μm to 10 μm, and more preferably in a range of 0.25 μm to 1 μm. If the second mask layer 5 is too thin, the catalyst layer 7 is formed on the sidewalls of the protruding portion 4 as well as on the top surface of the protruding portion 4. The portion of the catalyst layer 7 located on the sidewalls of the protruding portion 4 does not contribute to the etching in the thickness direction of the semiconductor substrate 1.

Herein, the “thickness t₁” is the distance from the top surface of the second mask layer 5 to the undersurface of the second mask layer 5 in the image, observed by the scanning electron microscope, of the cross-section that is parallel to the thickness direction of the second mask layer 5.

The ratio ti/hi of the thickness ti to the height h₁ is preferably 1 or more, and more preferably 1.5 or more. When the ratio t₁/h₁ is less than 1, the catalyst layer 7 is formed on the sidewalls of the protruding portion 4 as well as on the top surface of the protruding portion 4. As described above, the portion of the catalyst layer 7 located on the sidewalls of the protruding portion 4 does not contribute to the etching in the thickness direction of the semiconductor substrate 1. Though the upper limit of the ratio t₁/h₁ of the semiconductor substrate 1 is not particularly limited, it is usually 5 or less.

The foregoing etching method can be used to manufacture various articles. The foregoing etching method can also be used to form a recess or a through-hole or to divide a structure such as a semiconductor wafer. As one example, the foregoing etching method can be used to manufacture a semiconductor device. As another example, the foregoing etching method can be used in the manufacture of semiconductor chips which includes etching a surface of a semiconductor wafer and singulating the semiconductor wafer into semiconductor chips.

An Example and a Comparative Example will be described below.

### EXAMPLE

By performing the following method, a protruding portion, a second mask layer, and a catalyst layer were formed on a silicon substrate, and the protruding portion and the silicon substrate were etched using the catalyst layer. Then, after the etching was performed, whether the portion of the silicon substrate located right under the second mask layer became porous or not was investigated.

First, a first mask layer was formed on the surface of the silicon substrate. Specifically, a silicon wafer whose main surface was a (100) plane was used as the silicon substrate. To form the first mask layer, firstly, an inorganic material layer made of silicon oxide was formed on the silicon substrate. The inorganic material layer was formed by chemical vapor phase deposition (CVD). The thickness of the inorganic material layer was 0.42 μm. Then, a resist layer was formed on the inorganic material layer using photolithography. Then, the inorganic material layer was patterned by reactive ion etching using the resist layer as a mask. The reactive ion etching was performed using CHF₃ and Ar as etching gas, at flow rates of 20 sccm and 40 sccm for CHF₃ and Ar, respectively, at a pressure of 3 Pa, and at a high-frequency output of 200 W.

In this manner, the first mask layer with an opening having a forward tapered cross-sectional shape was formed. Herein, the opening in the first mask layer had a slit shape. The angle of inclination of the sidewalls of the opening, that is, the angle formed by the sidewalls of the opening with respect to the surface of the silicon substrate was 82°.

Then, a semiconductor layer was formed in a region corresponding to the opening of the first mask layer by epitaxial growth. The thickness of the semiconductor layer, that is, the height h₁ of the protruding portion, was 0.33 μm. The distance d₁ from the contour of the first orthogonal projection of the top surface of the protruding portion to a plane parallel to the surface of the silicon substrate to the contour of the second orthogonal projection of the lowest portion of the protruding portion to said plane was 0.05 μm. Therefore, the ratio h₁/d₁ of the height hi to the distance di was 6.7.

Then, the first mask layer was removed so that the second mask layer having an opening at a position corresponding to the protruding portion was formed on the silicon substrate. The second mask layer was formed by photolithography.

Then, a 50 mL plating solution containing an aqueous solution of hydrogen tetrachloroaurate (III) tetrahydrate and hydrofluoric acid was prepared.

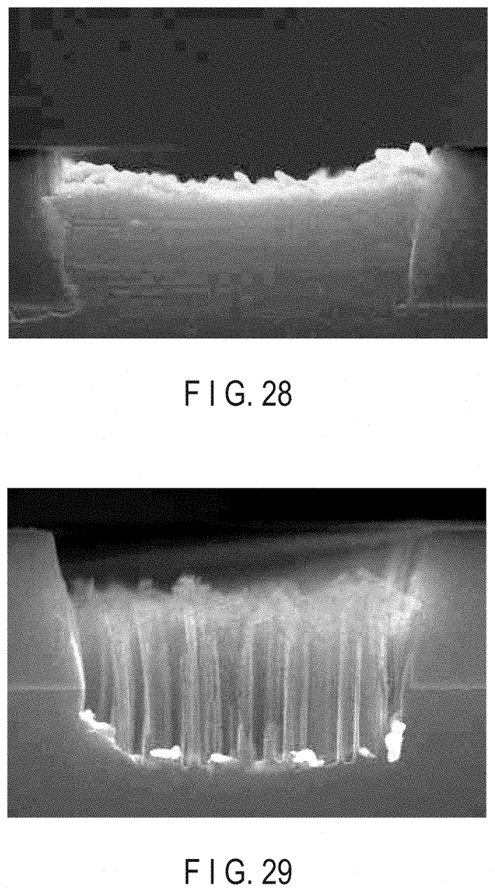

Then, the silicon substrate with the protruding portion and the second mask layer formed thereon was immersed in the plating solution at an ambient temperature for 60 seconds to form a catalyst layer on the top surface of the protruding portion. The immersion was performed without rotating the silicon substrate. FIG. 28 shows a micrograph of the silicon substrate provided with the catalyst layer. The micrograph shown in FIG. 28 was obtained by capturing, with the scanning electron microscope, an image of the cross-section of the silicon substrate provided with the catalyst layer that is parallel to the thickness direction of the silicon substrate.

Then, 27.5 mL hydrofluoric acid, 8.6 mL hydrogen peroxide, and 63.9 mL water were mixed to prepare a 100 mL etching solution. The silicon substrate with the protruding portion, the second mask layer, and the catalyst layer formed thereon was immersed in the etching solution at 25° C. for 30 minutes and etched. FIG. 29 shows a scanning electron micrograph of the silicon substrate after the etching.

FIG. 29 is a micrograph showing a cross-section of a structure obtained by etching the structure shown in FIG. 28. As shown in FIG. 29, according to the etching method of the Example, the portion of the silicon substrate located right under the second mask layer did not become porous.

### Comparative Example

A protruding portion, a second mask layer, and a catalyst layer were formed on a silicon substrate by the same method as described in the Example except that the cross-sectional shape of the opening of the first mask layer was a reverse tapered shape and that the angle of inclination of the sidewalls thereof was 100°, and the protruding portion and the silicon substrate were etched using the catalyst layer.

The cross-section of the silicon substrate after the etching that is parallel to the thickness direction of the silicon substrate was observed by the scanning electron microscope. The result was that the portion of the silicon substrate located right under the second mask layer was porous.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. An etching method comprising:
forming an uneven structure including a protruding portion on a surface of a semiconductor substrate, the protruding portion having a reverse tapered cross-sectional shape;
forming a catalyst layer on the surface of the semiconductor substrate at a top surface of the protruding portion, the catalyst layer including a noble metal; and
supplying an etching solution to the catalyst layer to etch the semiconductor substrate with an assist from the noble metal as a catalyst.

2. The etching method according to claim 1, wherein a ratio h₁/d₁ of a height h₁ of the protruding portion to a distance d₁ from a contour of a first orthogonal projection to a contour of a second orthogonal projection is in a range of 1 to 12, the first orthogonal projection being a orthogonal projection of the top surface of the protruding portion to a plane parallel to the surface of the semiconductor substrate, the second orthogonal projection being a orthogonal projection of a lowest portion of the protruding portion to said plane.

3. The etching method according to claim 1, wherein the protruding portion has a height in a range of 0.15 μm to 0.5 μm.

4. The etching method according to claim 1, wherein the forming of the uneven structure includes:
forming a first mask layer on the surface of the semiconductor substrate, the first mask layer including an opening having a forward tapered cross-sectional shape; and
forming a semiconductor layer on the surface of the semiconductor substrate at a position corresponding to the opening, the semiconductor layer filling at least a lower portion of the opening.

5. The etching method according to claim 4, wherein the semiconductor layer is formed by epitaxial growth.

6. The etching method according to claim 4, wherein the semiconductor layer includes Si.

7. The etching method according to claim 4, further comprising:
removing the first mask layer after forming the semiconductor layer; and
after removing the first mask layer, forming a second mask layer opening at a position corresponding to the protruding portion and having a top surface that is flush with or higher than the top surface of the protruding portion,
wherein the forming of the catalyst layer is performed in a presence of the second mask layer.

8. The etching method according to claim 7, wherein the supplying of the etching solution to the catalyst layer is performed with the second mask layer left on the semiconductor substrate.

9. The etching method according to claim 8, wherein the second mask layer is more etching-resistant to the etching solution than the protruding portion.

10. The etching method according to claim 1, wherein the etching solution includes a corrosive agent and an oxidizer.

11. The etching method according to claim 10, wherein the corrosive agent includes hydrofluoric acid, and
the oxidizer includes at least one of hydrogen peroxide, nitric acid, AgNO₃, KAuCl₄, HAuCl₄, K₂PtCl₆, H₂PtCl₆, Fe(NO₃)₃, Ni(NO₃)₂, Mg(NO₃)₂, Na₂S₂O₈, K₂S₂O₈, KMnO₄, and K₂Cr₂O₇.

12. The etching method according to claim 1, wherein the noble metal is Au.

13. A method of manufacturing a semiconductor chip, comprising etching a semiconductor wafer by the etching method according to claim 1 to singulate the semiconductor wafer into semiconductor chips, the surface of the semiconductor substrate being a surface of the semiconductor wafer.

14. A method of manufacturing an article, comprising etching the surface of the semiconductor substrate by the etching method according to claim 1.
